(19) United States
(12) Patent Application Publication
(10) Pub. No.: US 2009/0273000 A1
(43) Pub. Date: Nov. 5, 2009

(54) Light emitting device and method of manufacturing same

(75) Inventor: Shusaku Kon, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC LIGHTING, LTD., Tokyo (JP)

(21) Appl. No.: 12/385,449

(22) Filed: Apr. 8, 2009

(30) Foreign Application Priority Data
May 1, 2008 (JP) 2008-119607

(51) Int. Cl. H01L 33/00

(52) U.S. Cl. 257/98; 438/26; 438/29; 257/E33.061; 257/E33.059; 257/E33.066

(57) ABSTRACT

A light emitting device according to the present invention comprises board 2 having electrode 3b formed on the surface thereof, light emitting element 1 mounted on the surface of board 2, wire 4 for electrically connecting light emitting element 1 with electrode 3b, and reflector 11b formed on the surface of electrode 3b. Reflector 11b covers a connection between wire 4 and electrode 3b.

This application is based upon and claims the benefit of priority from Japanese patent application No. 2008-119607, filed on May 1, 2008, the disclosure of which is incorporated herein in its entirety by reference.

### BACKGROUND OF THE INVENTION

1. Field of the Invention

The present invention relates to a light emitting device which comprises a light emitting element, and a method of manufacturing the same.

2. Description of the Related Art

In a light emitting device which comprises a light emitting element such as LED (Light Emitting Diode) mounted on the surface of a board, the light emitting element is often connected to the board through wire bonding. Such a light emitting device comprises electrodes for connecting wires on the surface of the board.

FIG. 1A is a top plan view of a general light emitting device, and FIG. 1B is a cross-sectional view of the light emitting device. This light emitting device comprises board 102 which has electrodes 103a, 103b formed on a surface thereof, and light emitting element 101 mounted on the surface of electrode 103a. Light emitting element 101 and electrode 103b are connected through wire bonding with wire 104. The surface of board 102 of this light emitting device is covered with transparent sealant 105. Sealant 105 is formed of a transparent resin material in which a fluorescent material is dispersed.

In this light emitting device, when a voltage is applied between electrode 103a and electrode 103b, light emitting element 101 emits light. When the fluorescent material dispersed in sealant 105 is excited by the light which is emitted by light emitting element 101 and impinges on the fluorescent material, the fluorescent material emits light at a wavelength that is different from that of the light emitted by light emitting element 101.

Since the excited fluorescent light isotropically emits light in its surroundings, part of the light emitted by the fluorescent material is incident on the surfaces of board 102 and electrodes 103a, 103b. On the other hand, part of the light emitted by light emitting element 101 and fluorescent material, which travel outward beyond sealant 105, is totally reflected back by the interface between sealant 105 and the external space toward board 102, and is incident on the surfaces of board 102 and electrodes 103a, 103b.

Part of the light incident on the surfaces of board 102 and electrodes 103a, 103b is absorbed without being reflected. Accordingly, a smaller amount of light is absorbed by board 102 and electrodes 103a, 103b because the surfaces of board 102 and electrodes 103a, 103b have higher reflectivities, thus improving the light emission efficiency of the light emitting device.

Electrodes 103a, 103b are generally formed of gold (Au) or silver (Ag). However, gold characteristically exhibits low reflectivity in a blue region, while silver tends to be sulfurized and becomes dark, resulting in a sudden reduction of the reflectivity. For this reason, this light emitting device experiences difficulties in achieving a high light emission efficiency because light incident on electrodes 103a, 103b is largely absorbed.

JP-2007-324205-A describes a light emitting device which a reduction in light emission efficiency is inhibited. This light emitting device comprises a light emitting element which is mounted on a board which is formed with an electrode, the surface of which is coated with white resin. Then, the light emitting element and electrode are electrically connected through a wire. In this light emitting device, a reduction in the light emission efficiency can be inhibited because the amount of light absorbed on the board can be reduced by coating the surface of the electrode with white resin which has a higher reflectivity than the surface of the electrode.

However, the electrode of the light emitting device described in JP-2007-324205-A is not coated with the white resin in the vicinity of the connection between the wire and the electrode. Consequently, this light emitting device suffers from lower light emission efficiency because incident light is largely absorbed in the vicinity of the connection between the wire and the electrode.

### SUMMARY OF THE INVENTION

It is an object of the present invention to provide a light emitting device which exhibits a high light emission efficiency, and a method of manufacturing the same.

To achieve the above object, a light emitting device of the present invention includes a board having an electrode formed on the surface thereof, a light emitting element mounted on the surface of the board, a wire for electrically connecting the light emitting element with the electrode, and a reflector formed on the surface of the electrode, characterized in that the reflector covers a connection between the wire and the electrode.

The above and other objects, features and advantage of the present invention will become apparent from the following description with reference to the accompanying drawings which illustrate examples of the present invention.

### BRIEF DESCRIPTION OF THE DRAWINGS

FIG. 1A is a top plan view of a general light emitting device;

FIG. 1B is a cross-sectional view of the light emitting device shown in FIG. 1A;

FIG. 2A is a top plan view of a light emitting device according to a first embodiment of the present invention;

FIG. 2B is a cross-sectional view of the light emitting device shown in FIG. 2A;

FIG. 3 is a flow chart of a method for manufacturing the light emitting device shown in FIG. 2A;

FIG. 4A is a top plan view of a light emitting device according to a second embodiment of the present invention; and

FIG. 4B is a cross-sectional view of the light emitting device according to the second embodiment of the present invention.

### DESCRIPTION OF THE EXEMPLARY EMBODIMENTS

Next, embodiments of the present invention will be described with reference to the drawings.

### First Embodiment

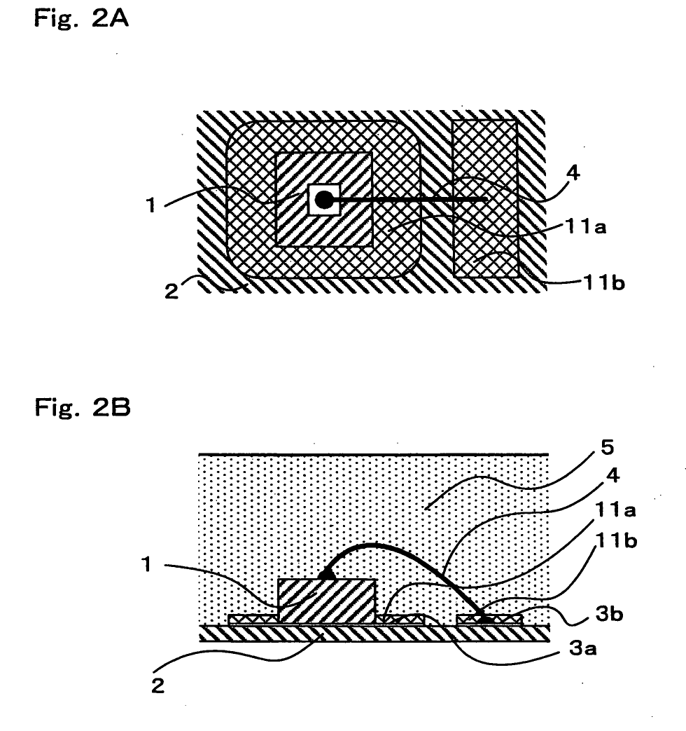

First, a light emitting device according to a first embodiment of the present invention will be described with reference to FIGS. 2A and 2B. FIG. 2A is a top plan view of the light emitting device according to this embodiment, and FIG. 2B is a cross-sectional view of the light emitting device.

The light emitting device according to the present invention comprises board 2 which has electrodes 3a, 3b formed on a surface thereof, and light emitting element 1 mounted on the surface of electrode 3a. Light emitting element 1 and electrode 3b are connected through wire bonding by wire 4 which is formed of gold. The surface side of board 2 of this light emitting device is coated with transparent sealant 5. Sealant 5 is formed of a transparent material, for example, a resin material, a glass material or the like in which a fluorescent material is dispersed.

Electrodes 3a, 3b are provided on their surfaces with reflectors 11a, 11b which have a higher reflectivity than the surfaces of electrodes 3a, 3b, respectively. Reflectors 11a, 11b are formed of a resin material.

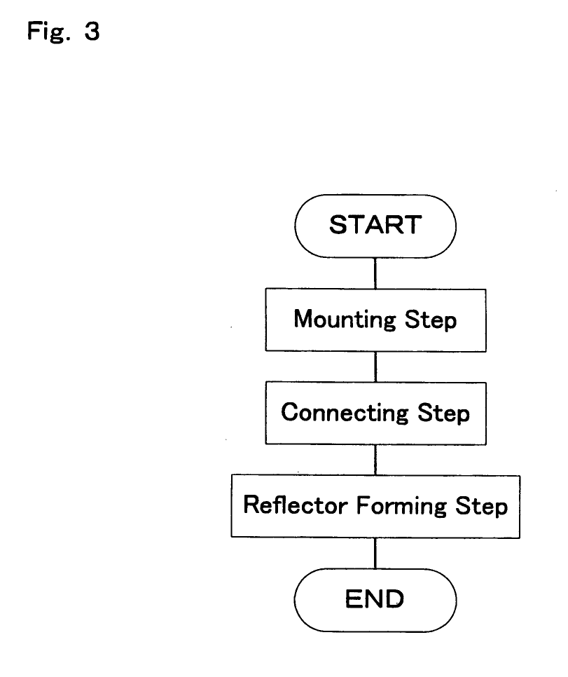

FIG. 3 is a flow chart of a method for manufacturing the light emitting device according to this embodiment. A reflector forming step for forming reflectors 11a, 11b involves a mounting step for mounting light emitting element 1 on the surface of electrode 3a, followed by a connecting step for connecting light emitting element 1 and electrode 3b through wire bonding using wire 4.

A reflector forming step involves discharging a resin material onto the surfaces of electrodes 3a, 3b using a dispenser to form reflectors 11a, 11b. The resin material is adjusted to have a viscosity such that the resin material naturally spreads over the surfaces of electrodes 3a, 3b after it has been discharged onto the surfaces of electrodes 3a, 3b.

Also, to improve the reflectivity of reflectors 11a, 11b, a white resin material is employed for forming reflectors 11a, 11b. A white resin material available herein may be, for example, an epoxy resin which is dispersed with white powder. The white powder may be powder such as titanium dioxide (TiO₂), aluminum oxide (Al₂O₃), magnesium oxide (MgO), boron nitride (BN), barium sulfate (BaSO₄), zinc oxide (ZnO) or the like, by way of example.

Light emitting element 1, which is a LED, emits light when a voltage is applied between electrode 3a and electrode 3b. The fluorescent material dispersed in sealant 5 emits light at a wavelength that is different from that of the light emitted by light emitting element 1 when it is excited by the light which is emitted by light emitting element 1 and impinges thereon.

Since the excited fluorescent material isotropically emits light in its surroundings, part of the light emitted by the fluorescent material is incident on the surfaces of board 2, electrodes 11a, 11b and the like. On the other hand, part of the light emitted by light emitting element 1 and fluorescent material, which travel outward beyond sealant 5, is totally reflected back by the interface between sealant 5 and the external space toward board 2, and is incident on the surfaces of board 2, electrodes 11a, 11b and the like.

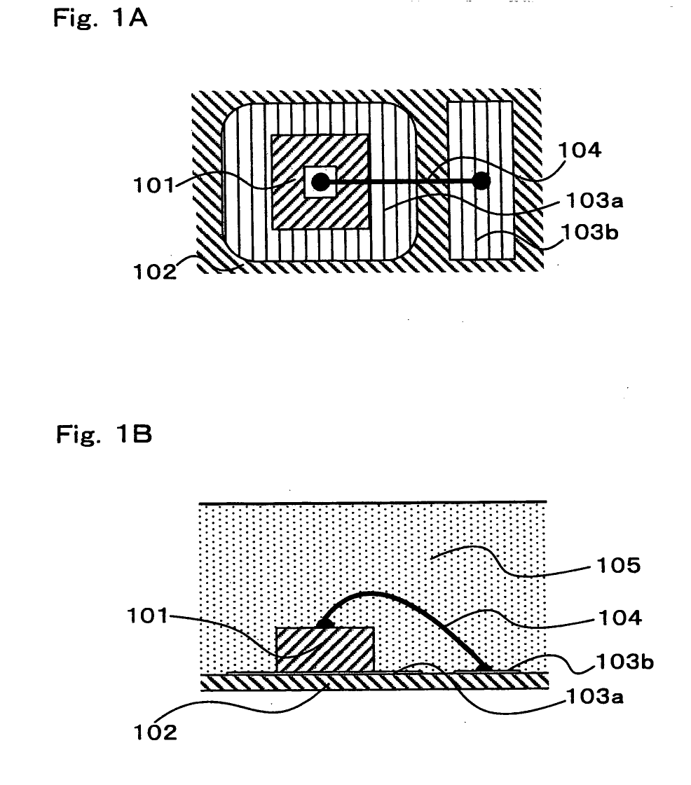

Light incident on the surfaces of the electrodes in the general light emitting device shown in FIG. 1A, is incident on the surfaces of reflectors 11a, 11b which have a higher reflectivity than the surfaces of the electrodes in the light emitting device according to this embodiment. Also, in the light emitting device described in JP-2007-324205-A, the white resin is not coated in the vicinity of the connection between the wire and the electrode, whereas in the light emitting device according to this embodiment, reflector 11b is formed in the reflector forming step after wire 4 has been connected to electrode 3b in the connecting step, so that reflector 11b can be applied even around the connection between electrode 3b and wire 4 without interstice.

As described above, since the light emitting device according to this embodiment can reduce the amount of light absorbed on the board, light emission efficiency is improved.

It should be noted that even if the fluorescent material is not dispersed in the sealant, light emission efficiency is improved because the light emitting device can reduce the amount of light absorbed on the board among light that is totally reflected back toward the board by the interface between the sealant and external space.

Also, not limited to the fluorescent material dispersed in the sealant, as found in the light emitting device according to this embodiment, a film-like fluorescent material, for example, may be disposed on or within the sealant.

### Second Embodiment

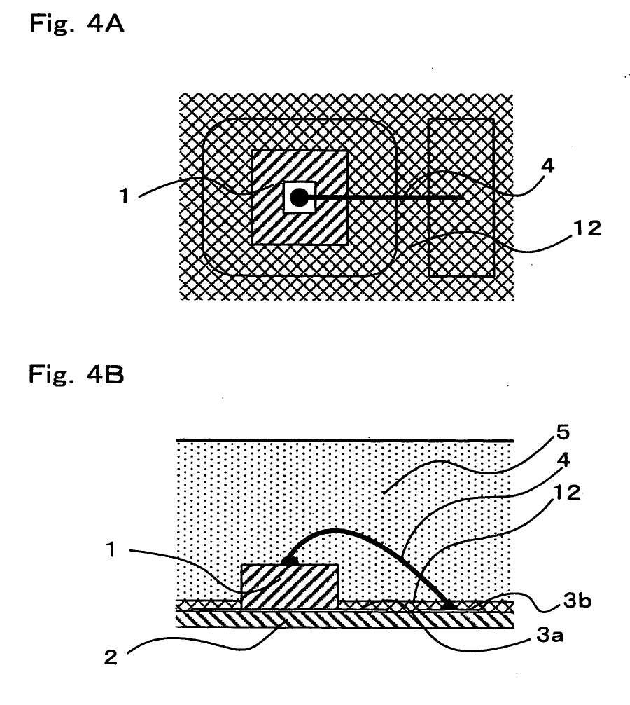

Next, a light emitting device according to a second embodiment of the present invention will be described with reference to FIGS. 4A and 4B. FIG. 4A is a top plan view of the light emitting device according to this embodiment, and FIG. 4B is a cross-sectional view of the light emitting device. As will be appreciated, the light emitting device according to this embodiment is configured in a manner similar to the light emitting device according to the first embodiment except for the configuration shown below, so that common parts are designated the same reference numerals.

In the light emitting device according to this embodiment, reflector 12 is formed not only on the surfaces of electrodes 3a, 3b but also on regions of the surface of board 2 on which electrodes 3a, 3b are not formed. A reflector forming step for forming reflector 12 is performed after completing a mounting step for mounting light emitting element 1 on the surface of electrode 3a, and a connecting step for connecting light emitting element 1 and electrode 3b through wire bonding with wire 4. In the reflector forming step, reflector 12 is formed by coating white resin material on board 2 by a spin coat method.

Also, the resin material used to form reflector 12 may be an insulating material such that electrode 3a and electrode 3b are not electrically connected through the reflector. Reflector 12 is formed, for example, of a resin material which includes powder dispersed in an epoxy resin, where the powder may be made of aluminum oxide, magnesium oxide, boron nitride or the like, which is an insulating material.

In the light emitting device according to this embodiment, since reflector 12 is provided not only on the surfaces of electrodes 3a, 3b but also on regions of the surface of board 2 on which electrodes 3a, 3b are not formed, high light emission efficiency can be achieved even if the surface of board 2 exhibits low reflectivity. Additionally, the reflector forming step can be carried out in a short time by collectively coating the resin material on board 2 to form reflector 12, so that the manufacturing cost can be reduced.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A light emitting device comprising:
a board having an electrode formed on a surface thereof;
a light emitting element mounted on the surface of said board;
a wire for electrically connecting said light emitting element with said electrode; and
a reflector formed on the surface of said electrode,
wherein said reflector covers a connection between said wire and said electrode.

2. The light emitting device according to claim 1, wherein said reflector is formed of a white resin material.

3. The light emitting device according to claim 2, wherein said resin material is dispersed with white powder.

4. The light emitting device according to claim 1, wherein said reflector has an insulating property, and said reflector covers the surfaces of said board and said electrode.

5. The light emitting device according to claim 1, wherein said board is covered with a transparent sealant on the surface side thereof.

6. The light emitting device according to claim 5, wherein said sealant includes a fluorescent material.

7. The light emitting device according to claim 1, wherein said light emitting element is a LED.

8. A method of manufacturing a light emitting device comprising:
a mounting step of mounting a light emitting element on a board on which an electrode is formed;
a connecting step of electrically connecting said light emitting element with said electrode through a wire; and
a reflector forming step of forming a reflector on at least the surface of said electrode, wherein said reflector forming step is performed after said mounting step and said connecting step.

9. The method of manufacturing a light emitting device according to claim 8, wherein said reflector forming step includes coating a white resin material.

10. The method of manufacturing a light emitting device according to claim 9, wherein said resin material is dispersed with white powder.

11. The method of manufacturing a light emitting device according to claim 9, wherein said reflector forming step includes discharging the resin material onto the surface of said electrode using a dispenser.

12. The method of manufacturing a light emitting device according to claim 9, wherein said resin material has an insulating property, and said reflector forming step includes coating the resin material onto said board by a spin coat method.

13. The method of manufacturing a light emitting device according to claim 8, wherein said light emitting element is a LED.
